(19) United States
(12) Patent Application Publication
(10) Pub. No.: US 2026/0246404 A1
(43) Pub. Date: Aug. 20, 2026

(54) METHOD FOR MONITORING THE CONTROL OF AN ELECTRONICALLY COMMUTATED ELECTRIC MACHINE

(71) Applicant: AUMOVIO Germany GmbH, Frankfurt am Main (DE)

(72) Inventors: Bogdan Budianu, Oberursel (DE); Dominik Schulte, Schulte (DE); Tom Kaufmann, Ippenschied (DE); Michael Wintzer, Frankfurt (DE)

(73) Assignee: AUMOVIO Germany GmbH, Frankfurt am Main (DE)

(21) Appl. No.: 19/545,592

(22) Filed: Feb. 20, 2026

(30) Foreign Application Priority Data
Feb. 20, 2025 (DE) 10 2025 106 472.5

(51) Int. Cl. H02P 8/36; H02P 3/02; H02P 8/00; H02P 8/34

(52) U.S. Cl. CPC H02P 8/36; H02P 3/02; H02P 8/005; H02P 8/34

(57) ABSTRACT

A method for monitoring the control of an electronically commutated electric machine a rotor and a stator, has the following steps: actuating the electric machine by means of a control device, wherein the rotor rotates in a first direction of rotation, sensing the back electromotive force of the coils of the stator, by a BEMF observer, outputting a fault message and/or transferring the electric machine to a safety operating state if at least one of two test conditions is met. An electronically commutated electric machine which is designed for carrying out the method, and to a brake device for a motor vehicle, comprising an electric machine of such type are also disclosed.

### TECHNICAL FIELD

A method for monitoring the control of an electronically commutated electric machine and an electronically commutated electric machine is disclosed.

### BACKGROUND

In modern motor vehicles, electronically commutated electric machines are used in a wide variety of applications. For example, electric machines, for example brushless electric motors, are often used as actuators, for example for window regulators or seat adjustment means.

The electric machine may comprise a stator and a rotor, wherein the rotor may be mounted in the stator. Such electric machines are generally fed via vehicle-internal energy stores that provide a direct voltage. A poly-phase, usually three-phase output current can be generated by means of a power converter (for example B6 bridge), which output current can be fed to the stator coils of the electric machine in order to generate a rotating rotary magnetic field by means of which the rotor can be made to rotate. The rotor may accordingly be designed to be permanently excited. The phases of the three-phase current generated by the power converter and of the associated rotating field are also referred to as motor phases.

For reliable control of the electric machine, it is important to know the exact rotor position or rotor orientation in order to be able to correspondingly control the output current of the phases, which is typically provided with pulse width modulation, or to be able to supply the motor phases with current at the correct time.

For this purpose, rotary position measuring systems are available which make it possible to determine the orientation or the rotor position of the rotor within the stator. In addition, various calibration methods can additionally be used to compensate for possible mechanical or electrical faults. Corresponding rotor position sensors, for instance Hall sensors, may be used to measure rotor position signals.

The contact systems used in these rotary position measuring systems generally rely on an uninterrupted electrical contacting, such that the control reliably functions. When using rotary position measuring systems, however, it is possible that correspondingly constructed contact systems, for instance under particular loads such as high temperatures or on account of mechanical stresses in components, dynamic influences or due to aging phenomena, lead to electrical contacting, in which short-term resistance fluctuations or even contact interruptions cannot be completely ruled out, so that under certain circumstances there are no longer any sensor signals for determining the rotor position.

In safety-relevant applications or fields of use of such electric machines, it may however be necessary for the control to be able to place the electric machine into an emergency operation or into a safety mode even if sensor signals are no longer available. When electric machines of such type are used, for example, in the field of electromechanical wheel brakes for motor vehicles, it may be required, for example, for the electromechanically actuable wheel brake to continue to remain functional even in the event of a failure of a sensor signal, or to fall into a safety operating state or into a fallback level ("RFE"), if it is no longer possible to determine the rotor position or the rotor orientation due to faulty or absent sensor signals.

For example, it may be required to detect in good time when the sensor signals are no longer available, in order to be able to output a fault message or to transfer the electric machine to a safety operating state.

A method for actuating an electronically commutated electric machine which at least mitigates, or does not exhibit, the above-mentioned aspects is therefore desirable.

### SUMMARY

An object is to rapidly detect when the rotor no longer follows the rotating stator field.

This object is achieved by a method for monitoring the control of an electronically commutated electric machine, a linear actuator and a brake device for a motor vehicle.

A first aspect comprises a method for monitoring the control of an electronically commutated electric machine having a rotor and a stator, having the following steps, for example in the sequence shown below: actuating the electric machine by means of a control device, wherein the rotor rotates in a first direction of rotation, sensing and/or observing the back electromotive force of the coils of the stator, preferably by means of a BEMF observer, outputting a fault message and/or transferring the electric machine to a safety operating state if at least one of the two test conditions is met: the validity condition of the BEMF observer is satisfied and the absolute value of the difference between the BEMF angular speed and the rotation speed of the stator rotating field reaches or exceeds a first rotation speed threshold, and wherein preferably a first time condition is satisfied, or the validity condition of the BEMF observer is not satisfied and the rotation speed of the stator rotating field exceeds a second rotation speed threshold, for example a second time condition is satisfied.

It is possible to transfer the electronically commutated electric machine to a safety operating state even in the event of failure of at least one or all of the sensor signals of a rotor position sensor. The method thus provides additional safety for the operation of such electric machines, which means that important positions of the rotor, for example end positions or end stops, can still be achieved even in the event of failure of the sensor signals. Therefore, referencing of the electric machine can be made possible in such situations as well. As a result, possible damage to the electric machine can be avoided and, after successful referencing, continued operation can also be made possible.

The electronically commutated electric machine may comprise a stator and a rotor, wherein the rotor may be designed to be permanently excited and wherein the stator may have coils or induction coils which can be electrically energized for actuation in order to generate a rotating magnetic field or rotating stator field. According to an embodiment, the rotor is mounted within the stator. However, the embodiments can also be used for other designs, for example current-excited rotors.

Thus, it is possible to use the electronically commutated electric machine for driving a linear actuator or together with a linear actuator. The first direction of rotation may for example indicate a brake application direction and the second direction of rotation a release direction.

In this way, the method can also be used for, for example, an electromechanically actuatable wheel brake of a motor vehicle, which often have electrically driven linear actuators as pressure setting means.

Accordingly, in a further aspect, to a linear actuator comprising an electronically commutated electric machine having a rotor and a stator, designed to carry out a method as stated above.

Furthermore, the embodiments also relate, in yet a further aspect, to a brake device of a motor vehicle, comprising a linear actuator of such type, for example as a pressure setting device for an electromechanically actuatable wheel brake.

The embodiments makes use of the so-called back electromotive forces (BEMF). The methods based thereon are therefore also referred to as BEMF methods. By means of the BEMF method, induced voltage signals as a consequence of a back electromotive force, which signals are induced in the phase windings by the magnets of the rotor, can be detected. Accordingly, a BEMF method can be used at least in the safety operating mode. The BEMF method can be implemented, for example, by correspondingly designed function blocks in the control unit, wherein these function blocks or circuit arrangements can then constitute the BEMF observer. The method accordingly operates - at least in the safety operating mode - without sensors. This means that, at least in the safety operating mode, there is no need to use any sensor signals of an additional position sensor, such as, e.g., a Hall sensor, which facilitates the use of BEMF methods for such cases.

The back electromotive forces are proportional to the rotational speed of the rotor and therefore permit, for example at relatively high rotational speeds, a rotor position determination which can be used for the control and motor regulation by the control unit. The back EMF thus reflects the instantaneous angular speed of the rotor. The voltage corresponds to the back EMF, which can be observed.

A known method for detecting the back EMF is known, for example, from WO2024/132553, and will therefore only be briefly outlined here. In the BEMF method described, the rotor flux is estimated by a BEMF observer, or the BEMF information is extracted from relationships of voltage and current in relation on the basis of a motor model. In electric machines or AC electric machines, such as for example synchronous machines having permanent magnets, BEMF methods can normally be used very well for estimating the rotor position and rotor speed. A BEMF observer may comprise complex estimation algorithms, wherein correction terms can be used on the basis of measured and estimated signals. In this case, provision may be made for correction terms based on measured and estimated currents in a α-β-stationary reference frame to also be provided for the BEMF observer. A possible procedure for estimating rotor flux is disclosed in WO2024/132553, which is hereby incorporated in full. The determination of the back EMF is also described in more detail in US 9,484,849, which is also hereby incorporated in full.

At higher speeds of the rotor, the voltage can be detected easily since the forces acting are sufficiently high. However, at relatively low rotational speeds, for example below 500 or 400 rpm depending on the design of the electric machine, detection proves to be more difficult, or no longer possible, since the induced forces are lower and ultimately can no longer be detected without error.

The embodiments utilize these effects.

Here, the electric machine may firstly be actuated by the control device, wherein the rotor rotates in a first direction of rotation. This may take place on the basis of an actuation control command, for example on the basis of a braking requirement in an electromechanically actuatable wheel brake, such that application of the wheel brake by the linear actuator occurs upon a rotation of the rotor in the first direction of rotation. By means of the control command, the motor phases of the electric machine can accordingly each be supplied with a PWM signal, based on a current measurement for generating the rotary magnetic field, in such a way that the rotor rotates. Thus, in a current vector mode, a rotating magnetic field is generated in the stator ("rotating stator field"), which rotating field is followed by the rotor. In the context of the invention, it is assumed that a rotational speed (n) is proportional to an angular speed (ω) and the rotational speed can be calculated from the angular speed. In this respect, the two terms are used interchangeably.

If sensor signals are no longer present, the rotor position and thus the position of the linear actuator are not always known. However, in the case of electromechanically actuatable wheel brakes, for example, the linear actuator must be retracted to an initial or zero position after each braking process, that is to say after each application of the wheel brake for the application of an application force.

According to an embodiment, therefore, the detection and/or observation of the back electromotive force of the coils of the stator is provided. For this purpose, it is advantageous to use a BEMF observer.

The BEMF observer may be designed to output and/or estimate a BEMF angle or rotor angle and a BEMF angular speed of the rotor. From this, it is possible to estimate for example the rotor position.

For the purpose of monitoring the functionality of the electric machine, the BEMF angular speed of the rotor can be used and compared with the applied stator rotating field. If the absolute value of the difference between the BEMF angular speed and the stator rotating field reaches or exceeds a first rotational speed threshold, this indicates that the rotor is no longer following the applied rotating magnetic field as desired. The first rotational speed threshold thus indicates a limit for a tolerable deviation between the stator rotation field and the BEMF angular speed or the rotational speed of the rotor. Since the back electromotive forces which occur become small at low rotational speeds of the rotor, it is possible that the BEMF angular speed of the rotor cannot be correctly output by the BEMF observer.

In order to avoid a situation in which an error message is issued or the electric machine is transferred to the safety operating state in such cases, according to the invention a validity condition ("BEMF validity") can be introduced in addition to the absolute value of the difference. This requirement can be satisfied when a BEMF observer error does not exceed a predefined limit value, and/or when the output amplitude of the acquired BEMF signals exceeds a predetermined limit value. This may indicate that the validity condition is satisfied. The BEMF observer error can be obtained here from the difference between the measured phase currents and the modeled phase current of the observer.

If the absolute value of the difference between the BEMF angular speed and the stator rotating field now reaches or exceeds the first rotation speed threshold and additionally the BEMF observer error indicates that the validity condition is satisfied, this indicates an error in the region of the electric machine, for example that the rotor does not follow the stator rotating field. In other words, in such a case, the back electromotive forces are strong enough to be able to be detected, which indicates a validity of the BEMF signals, and at the same time the measured BEMF angular speed and the rotation speed of the stator rotating field deviate from one another by a magnitude which is above the first rotational speed threshold or a tolerable deviation, such that an error can be assumed.

In addition to this first test condition, a further second test condition may be set which likewise permits monitoring of the electric machine according to the invention. As a result, a further possible error case can be detected. In this case, it is possible to check whether the rotational speed of the stator rotating field exceeds a second rotational speed threshold, and whether the validity condition is complied with in this case. If the second rotational speed threshold indicates a value at which back electromotive forces can be detected, the validity condition of the BEMF observer is satisfied during proper operation. In other words, if the stator rotating field exceeds a second rotation speed threshold and at the same time the validity condition of the BEMF observer is not satisfied, this indicates an error in the region of the electric machine.

In order to bridge a possible time period in dynamic situations in which the rotor does not immediately follow the rotating stator field after an actuation, it may furthermore be determined that the above mentioned test conditions are to be present over a predetermined period of time or a predetermined number of sampling steps. This makes it possible to prevent such one-off incorrect signals from leading to incorrect recognition.

For example, a time condition can be provided, according to which the above first and/or second test condition should be satisfied over a time period of at least 100 ms, preferably of at least 200 ms or even more. In this case, a first time condition can be stipulated for the first test condition and a second time condition can be stipulated for the second test condition, which may be useful for cases in which the one test condition is more critical than the second test condition.

Further details of the embodiments will emerge from the description of the illustrated exemplary embodiments and from the appended claims.

### BRIEF DESCRIPTION OF THE DRAWINGS

In the drawings:

FIG. 1 shows an exemplary representation of a circuit with a BEMF observer,

FIG. 2 shows a more detailed exemplary circuit arrangement of the BEMF observer from FIG. 1, and

FIG. 3 shows a functional diagram of the method.

### DETAILED DESCRIPTION

In the following detailed description of embodiments, identical reference numerals for the sake of clarity denote substantially identical parts in or on these embodiments. To better illustrate the embodiments illustrated in the figures are however not always drawn to scale.

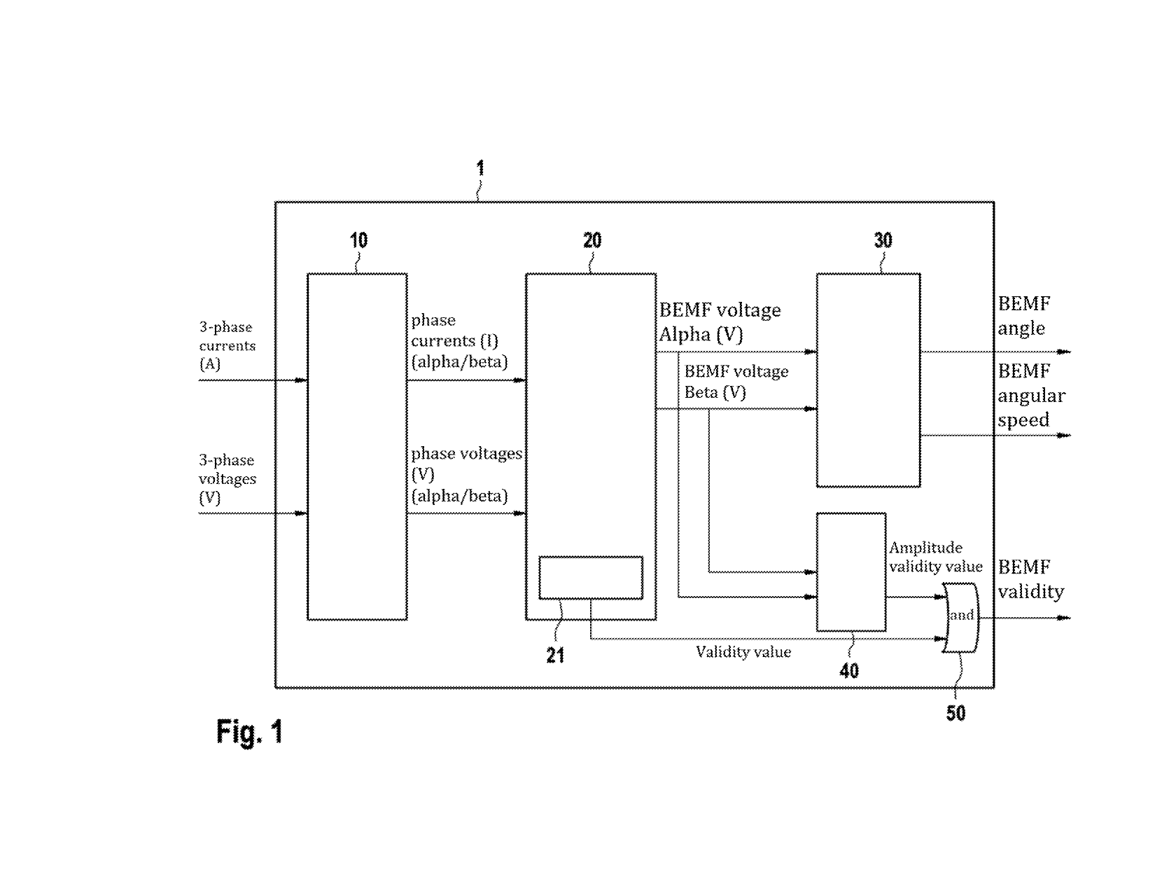

FIG. 1 shows an exemplary representation of a circuit 1 with a BEMF observer 20. The circuit 1 is integrated in the control device of the electronically commutated electric machine (not shown), but can also be implemented in a superordinate control unit.

Where an observer is referred to in the context of the embodiments, this may generally be understood to mean means or electronic circuits that allow a corresponding control implementation of the desired functionality. The implementation can be carried out by means of a function block with a corresponding circuit arrangement.

The electronically commutated electric machine is embodied as a three-phase electric motor and, in addition to the control device for actuation, comprises a permanently excited rotor and a stator with coils which can be energized via electrical line paths.

From the measured voltages in the stator coils, it is possible to calculate the voltage which is induced in the stator windings by the movement of the rotor.

Three phase currents and three phase voltages are shown here as input variables for the circuit 1. The input variables are based on measured stator currents and measured or estimated stator voltages. These are transferred into a stationary α-β coordinate system by a function block 10, which performs a Clarke transformation in the example.

The phase currents and phase voltages in the α-β coordinate system are then supplied to the BEMF observer 20, which comprises appropriate means for calculating the BEMF voltages in the α-β coordinate system. The BEMF voltages in the α-β coordinate system are transmitted to an angle observer 30, which outputs the BEMF angle and the BEMF angular speed from these values. The rotor position or the rotor orientation can be determined from these values.

The BEMF observer 20 also comprises a validity observer 21, which observes the transient response. A corresponding limit value can be determined for this purpose. If the transient response has the desired quality, a corresponding signal ("valid" = "true") can be output as a validity value to an AND link 50, which corresponds more or less to a quality criterion of the signal quality of the BEMF observer.

In addition, the magnitude of the amplitudes of the BEMF voltages in the α-β coordinate system is checked by an amplitude observer 40, which outputs a further amplitude validity value to the AND link 50. The magnitude of the amplitude is proportional to the rotor rotation speed and thus constitutes a further quality criterion. An amplitude that is too low can indicate problems in the system, such as faults such as short circuits, open circuits, or other anomalies. Particularly at low rotational speeds, at which the back EMF becomes very low, the signal quality can be impaired, so that the validity condition cannot be satisfied.

Insofar as the validity value from the validity observer 21 and the amplitude validity value satisfy the required criteria, the AND link 50 outputs a corresponding signal for the BEMF validity, which indicates that the validity condition of the BEMF observer is satisfied.

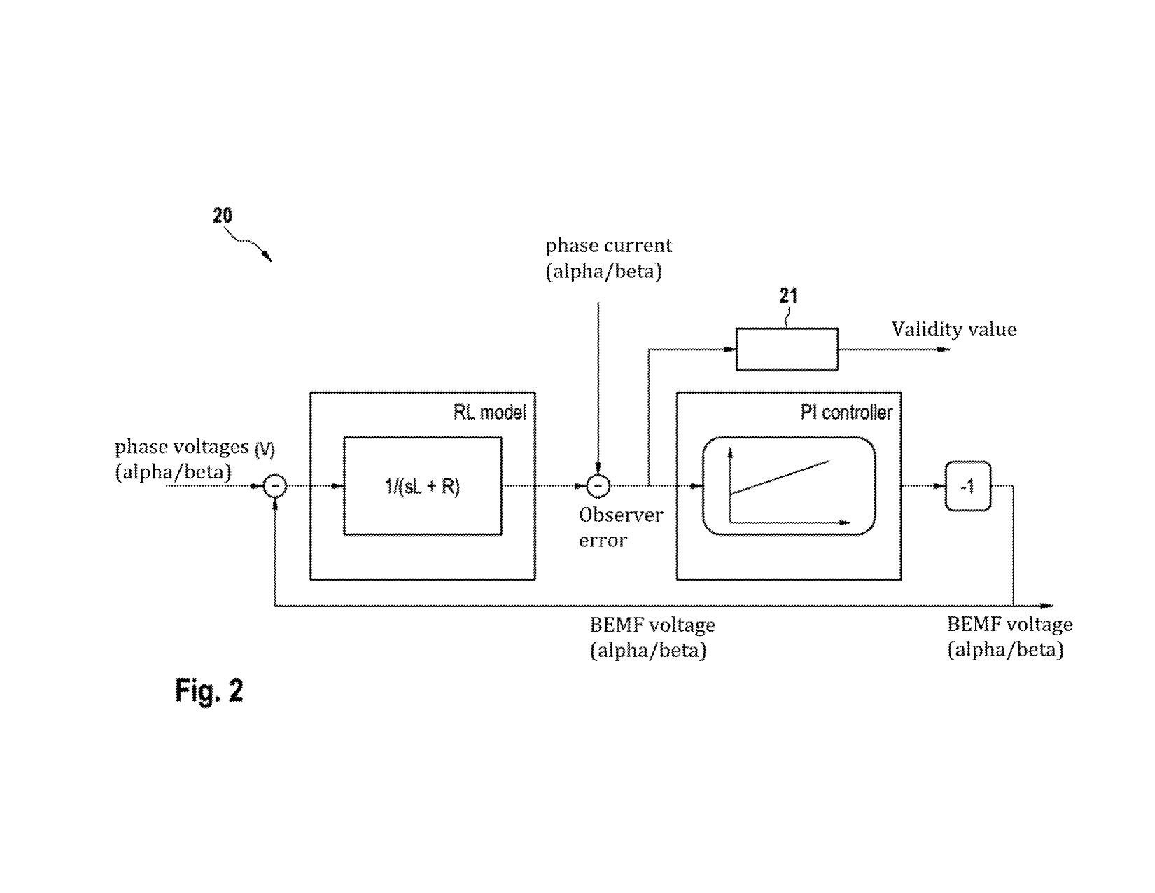

FIG. 2 shows a more detailed exemplary circuit arrangement of the BEMF observer 20 from FIG. 1. For the validity observer 21, a value for the current of 1 A can be specified, for example, as a prescribed threshold, which of course can also have other threshold values adapted to the electric machine. The BEMF voltages in the α-β coordinate system (BEMF voltage alpha/beta) and the validity value (value = "true" or "false") are output variables.

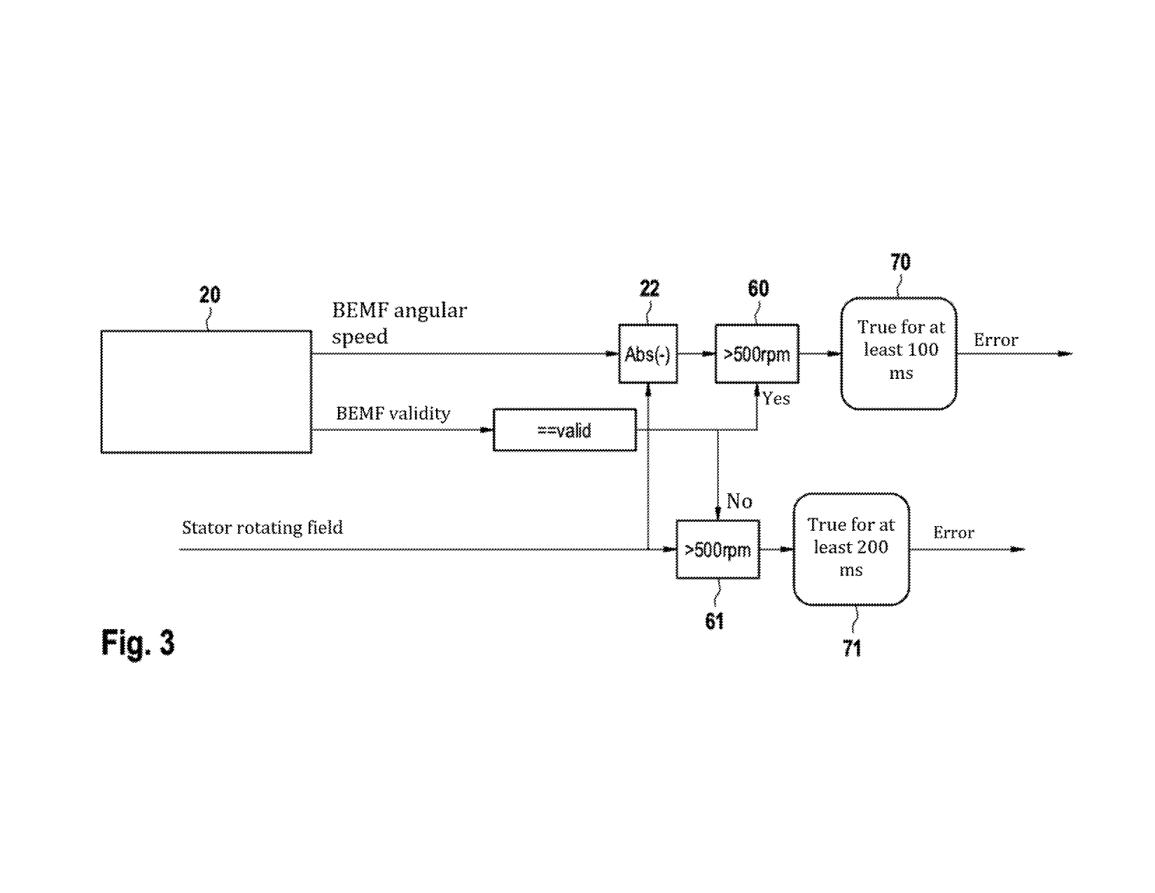

FIG. 3 shows an exemplary functional diagram of the method according to the invention.

The method for actuating an electronically commutated electric machine having a rotor and a stator accordingly has the following steps in the sequence illustrated: activating the electric machine by means of a control device, wherein the rotor rotates in a first direction of rotation, sensing and/or observing the back electromotive force of the coils of the stator, preferably by means of a BEMF observer, outputting a fault message and/or transferring the electric machine to a safety operating state if at least one of the two test conditions is met: the validity condition of the BEMF observer is satisfied and the absolute value of the difference between the BEMF angular speed and the rotation speed of the stator rotating field reaches or exceeds a first rotation speed threshold, and wherein for example a first time condition is satisfied, or the validity condition of the BEMF observer is not satisfied and the rotation speed of the stator rotating field exceeds a second rotation speed threshold, wherein for example a second time condition is satisfied.

In an embodiment, the electronically commutated electric machine is used for driving a linear actuator or together with a linear actuator. According to one embodiment, the linear actuator is used as a pressure setting device in a brake device of a motor vehicle.

The electric machine is actuated by the control device, wherein the rotor rotates in a first direction of rotation. This may take place on the basis of an actuation control command in a normal operating mode. The control device may self-evidently also be embedded in a superordinate central controller.

For the purpose of monitoring the functionality of the electric machine, the BEMF angular speed of the rotor may be used and compared with the applied stator rotating field. If the absolute value of the difference between the BEMF angular speed and the stator rotating field reaches or exceeds a first rotational speed threshold, this indicates that the rotor is no longer following the applied rotating magnetic field as desired. For this purpose, the function block 22 in which these two variables are combined is provided in FIG. 3.

In addition, according to the invention, a check is carried out to determine whether the validity condition ("BEMF validity") is satisfied. This requirement is deemed to be satisfied when a BEMF observer error does not exceed a predefined limit value, and/or when the output amplitude of the acquired BEMF signals exceeds a predetermined limit value.

A check is made in the first rotational speed tester 60 as to whether the first rotational speed threshold is reached, provided that the validity condition is satisfied. In the example shown, a value of 500 rpm is specified as the first rotational speed threshold solely for illustrative purposes, said value permitting the formation of back electromotive forces in the electric machine under consideration. Of course, other values are also possible and provided depending on the specific electric machine.

If this first test condition is satisfied, a first time checker 70 is used to check whether this first test condition has been satisfied over a predetermined period of time. In the exemplary embodiment, a predetermined time duration of 100 ms is specified purely by way of example. If this first time condition is then satisfied, a fault message is generated and/or the electric machine is transferred to a safety operating state.

A second test condition checks whether the speed of the stator rotating field exceeds a second rotational speed threshold and whether the validity condition is complied with in this case. In FIG. 3, for this purpose, a second rotational speed tester 61 is provided, which receives the corresponding signals relating to the rotational speed of the stator rotating field. In the example shown, the value 500 rpm is likewise specified as the second rotational speed threshold solely for illustrative purposes, wherein this value does not have to correspond to that of the first rotational speed threshold.

If the BEMF validity is then not given or not satisfied, a second time checker 71 is used to check whether this second test condition is satisfied over a predetermined period of time. In the exemplary embodiment, a predetermined time duration of 200 ms is specified purely by way of example.

If this second time condition is then satisfied, a fault message is generated and/or the electric machine is transferred to a safety operating state.

Transferring the electric machine to a safety operating state may comprise one of the following steps: shutting down the electric machine, switching the electric machine to a fallback level, switching the electric machine into an inactive state.

1. A method for monitoring control of an electronically commutated electric machine having a rotor and a stator comprising:
actuating the electric machine with a control device, wherein the rotor rotates in a first direction of rotation;
sensing back electromotive force of coils of the stator, with a back electromotive force (BEMF) observer; and
at least one of outputting a fault message and transferring the electric machine to a safety operating state when at least one of:
a validity condition of the BEMF observer is satisfied and the absolute value of the difference between the BEMF angular speed and the rotation speed of the stator rotating field reaches or exceeds a first rotation speed threshold, and wherein a first time condition is satisfied, or
the validity condition of the BEMF observer is not satisfied and the rotation speed of the stator rotating field exceeds a second rotation speed threshold, and wherein a second time condition is satisfied.

2. The method according to claim 1, wherein the rotor is permanently excited and wherein the stator has coils which can be electrically energized for actuation in order to generate a rotating magnetic field.

3. The method according to claim 1, wherein the method is executed continuously during actuation or during operation of the electric machine.

4. The method according to claim 1, wherein the control device supplies the motor phases of the electric machine in each case with a PWM signal based on a current measurement for generating a rotary magnetic field in such a way that the rotor rotates.

5. The method according to claim 1, wherein the rotational speed of the rotor is detected on the basis of the observation of the back electromotive force of the coils of the stator, from which the angular speed of the rotor is determined.

6. The method according to claim 1, wherein the rotational speed of the rotor is detected without sensors.

7. The method according to claim 1, wherein the validity condition of the BEMF observer is satisfied when a BEMF observer error does not exceed a prescribed limit value and when the magnitude of the amplitudes of the BEMF voltages exceeds a predetermined limit value.

8. The method according to claim 1, wherein the first rotational speed threshold indicates a limit of a tolerable deviation between the rotation speed of the stator rotating field and the BEMF angular speed.

9. The method according to claim 1, wherein the second rotational speed threshold indicates a value at which back electromotive forces can be detected.

10. The method according to claim 9, wherein at least one of the first and the second rotational speed threshold is at least 500 rpm.

11. The method according to claim 1, wherein at least one of the first and the second time condition is at least 100 ms.

12. The method according to claim 1, wherein transferring the electric machine to a safety operating state comprises at least one of:
shutting down the electric machine;
switching the electric machine to a fallback level; and
switching the electric machine into an inactive state.

13. The method according to claim 1, wherein the electric machine is used to drive a linear actuator, wherein the linear actuator has at least one end stop.

14. A linear actuator comprising:
an electronically commutated electric machine having a rotor and a stator wherein the rotor rotates in a first direction of rotation; and
a control device with instructions for:
sensing back electromotive force of coils of the stator, with a back electromotive force (BEMF) observer; and
at least one of outputting a fault message and transferring the electric machine to a safety operating state when at least one of:
a validity condition of the BEMF observer is satisfied and the absolute value of the difference between the BEMF angular speed and the rotation speed of the stator rotating field reaches or exceeds a first rotation speed threshold, and wherein a first time condition is satisfied; and
the validity condition of the BEMF observer is not satisfied and the rotation speed of the stator rotating field exceeds a second rotation speed threshold, and wherein a second time condition is satisfied.

15. A brake device of a motor vehicle, comprising:
a linear actuator;
an electronically commutated electric machine having a rotor and a stator wherein the rotor rotates in a first direction of rotation; and
a control device with instructions for:
sensing back electromotive force of coils of the stator, with a back electromotive force (BEMF) observer; and
at least one of outputting a fault message and transferring the electric machine to a safety operating state when at least one of:
a validity condition of the BEMF observer is satisfied and the absolute value of the difference between the BEMF angular speed and the rotation speed of the stator rotating field reaches or exceeds a first rotation speed threshold, and wherein a first time condition is satisfied; and
the validity condition of the BEMF observer is not satisfied and the rotation speed of the stator rotating field exceeds a second rotation speed threshold, and wherein a second time condition is satisfied.
